(19) United States
(12) Patent Application Publication
(10) Pub. No.: US 2026/0214867 A1
(43) Pub. Date: Jul. 23, 2026

(54) HEAT EXCHANGER WITH VARIABLE BASE THICKNESS AND FIN HEIGHT

(71) Applicants: DENSO International America, Inc., Southfield, MI (US); DENSO CORPORATION, Kariya (JP)

(72) Inventor: Siddharth DASGUPTA, Windsor (CA)

(21) Appl. No.: 19/090,746

(22) Filed: Mar. 26, 2025

Related U.S. Application Data
(60) Provisional application No. 63/748,493, filed on Jan. 23, 2025.

(51) Int. Cl. H05K 7/20; F28F 3/02

(52) U.S. Cl. CPC H05K 7/2089; F28F 3/02; F28F 2215/04

(57) ABSTRACT

A heat sink for a power inverter assembly is provided. The heat sink includes a base having a lower surface and an opposing upper surface that define a thickness of the base, wherein the lower surface contacts a heat-generating device. A plurality of fins extend from the upper surface. The fins include a first group of fins extending directly from a first region of the base, and a second group of fins extending directly from a second region of the base. The first region of the base has a first thickness, and the second region of the base has a second thickness that differs from the first thickness. The variable base thickness allows for customized and particular adjustment to heat transfer capabilities of the heat sink.

### CROSS-REFERENCE TO RELATED APPLICATION

This application claim the benefit of U.S. Provisional Application No. 63/748,493 filed Jan. 23, 2025, titled “VARIABLE BASE THICKNESS AND FIN HEIGHT HEAT EXCHANGER”, the entire disclosure of which is incorporated by reference herein.

### TECHNICAL FIELD

The present disclosure relates to a heat sink having a variable base thickness and/or a variable fin height.

### BACKGROUND

The performance, lifespan, and safety of many electrical components are dependent on the temperature at which the electrical components operate and a build-up of heat can negatively affect these elements. The temperature of the electrical component may be affected by heat generated from the electrical component or its surrounding environment. Heat sinks are used to dissipate heat from electrical components or other heat-generating devices and prevent the negative effects from a build-up of heat. Some heat sinks use pin fins that extend outward from a base that is in thermal communication with the electrical component. As fluids (e.g., air, water, or the like) flow along the heat sink in between the pin fins, the pin fins transfer the heat from the electrical component to the fluid, cooling the electrical component.

### SUMMARY

In an embodiment, a heat sink for a power inverter assembly in a motor vehicle comprises: a base having a lower surface and an opposing upper surface that define a thickness of the base, wherein the lower surface contacts a heat-generating device; and a plurality of fins extending from the upper surface of the base, wherein the plurality of fins include a first group of fins extending directly from a first region of the base, and a second group of fins extending directly from a second region of the base; wherein the first region of the base has a first thickness, and the second region of the base has a second thickness that differs from the first thickness.

In an embodiment, a power inverter assembly for a motor vehicle comprises: a heat-generating component; and a heat sink having: a base that includes a lower surface, an upper surface, and a thickness therebetween, wherein the lower surface contacts the heat-generating component; an inlet region at or near an inlet of the heat sink; an outlet region at or near an outlet of the heat sink, wherein fluid flows from the inlet to the outlet; and a plurality of fins extending from the upper surface of the base, wherein the plurality of fins include a first group of fins in the inlet region and a second group of fins in the outlet region; wherein the thickness of the base at the inlet region is different than the thickness of the base at the outlet region, and wherein the first group of fins have a different height than the second group of fins.

In an embodiment, a power inverter assembly for a motor vehicle comprises: a heat sink having a base that includes a lower surface, an upper surface, a thickness therebetween, and a plurality of fins extending from the upper surface of the base, wherein the heat sink includes an inlet region and an outlet region such that fluid flows across the heat sink from the inlet region to the outlet region, and wherein the heat sink has a width extending in a lateral direction and a length extending in a longitudinal direction perpendicular to the lateral direction; a plurality of heat-generating components contacting the lower surface of the base, wherein the heat-generating components are distributed along a first lateral side of the base, and wherein the base has a second lateral side; wherein the thickness of the base in the first lateral side is less than the thickness of the base in the second lateral side.

### BRIEF DESCRIPTION OF THE DRAWINGS

FIG. 1A is a perspective view of a heat sink, according to an embodiment.

FIG. 1B is a perspective view of an opposite side of the heat sink of FIG. 1A, according to an embodiment.

FIG. 2 is a side view of a portion of a heat sink according to an embodiment.

FIG. 3 is a side view of a portion of a heat sink according to another embodiment.

FIG. 4A is a side view of a portion of a heat sink according to another embodiment; FIG. 4B is a front view of the portion illustrated in FIG. 4A.

FIG. 5A is a top view of a heat sink according to an embodiment; FIG. 5B is a cross-sectional view taken along line 5B-5B of FIG. 5A.

FIG. 6 is a side view of a portion of a heat sink according to another embodiment.

FIG. 7 is a side view of a portion of a heat sink according to another embodiment.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

An inverter card is an electronic component used to convert direct current (DC) to alternating current (AC), typically in applications such as powering AC motors, lighting, and other devices from a DC source. In an automotive setting, power inverter assemblies are critical components in automotive electric drive systems, converting DC from a battery into AC to drive an electric motor. These inverters utilize power cards, which contain semiconductor switches such as insulated-gate bipolar transistors (IGBTs) or metal-oxide-semiconductor field-effect transistors (MOSFETs) to regulate power flow. During operation, these semiconductor components generate significant amounts of heat, necessitating efficient cooling to maintain performance and reliability.

To manage thermal loads, inverter assemblies are commonly equipped with heat exchangers or heat sinks, typically made from thermally conductive metals such as aluminum or copper. These heat sinks are often integrated with a liquid cooling system, where a coolant fluid flows through the assembly to absorb and dissipate heat. However, a common problem with heat sinks, particularly in liquid-cooled systems, is uneven cooling distribution due to temperature gradients in the coolant as it flows from the inlet to the outlet. When the coolant first enters the heat sink, it is at its lowest temperature, allowing for efficient heat transfer from the components to the coolant. However, as the coolant absorbs heat along its path, it gradually warms up, decreasing its ability to absorb additional heat near the outlet. This results in uneven cooling efficiency, where components near the coolant inlet receive the most effective cooling, while those closer to the outlet experience reduced cooling efficiency. This temperature gradient can lead to localized hot spots, making it challenging to maintain consistent cooling performance across all components. Optimizing coolant flow and temperature regulation is essential in managing this phenomenon, especially in high-power applications where thermal balance is critical.

The present disclosure addresses this problem by introducing a variable thickness in the base of the heat sink. Specifically, the base of the heat sink, from which the pins or fins extend from, can have a relatively large thickness in certain areas and a relatively small thickness in other areas. The thickness can vary in the direction from outlet to inlet. For example, the base may be thicker in the area of the inlet, and thinner in the area of the outlet. Alternatively, in some embodiments, the base may be thicker in the area of the outlet, and thinner in the area of the inlet. The variable base thickness at these strategic locations can improve heat transfer and reduce pressure drops, while maintaining structural durability.

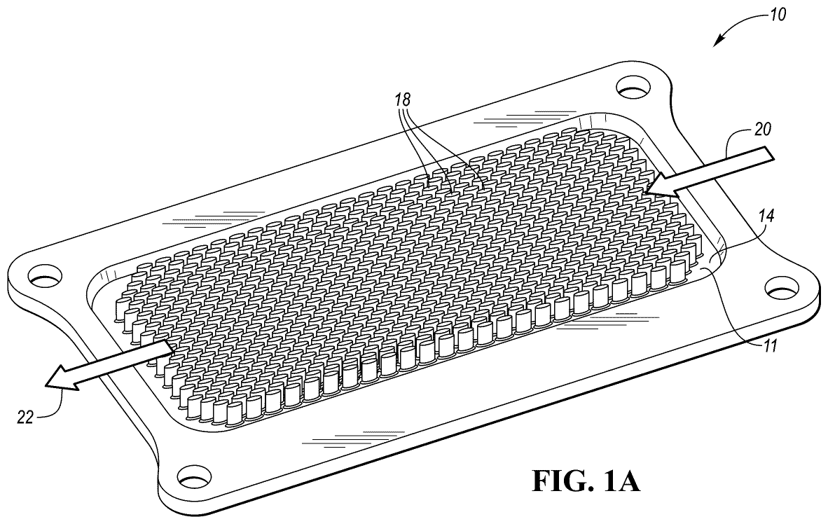

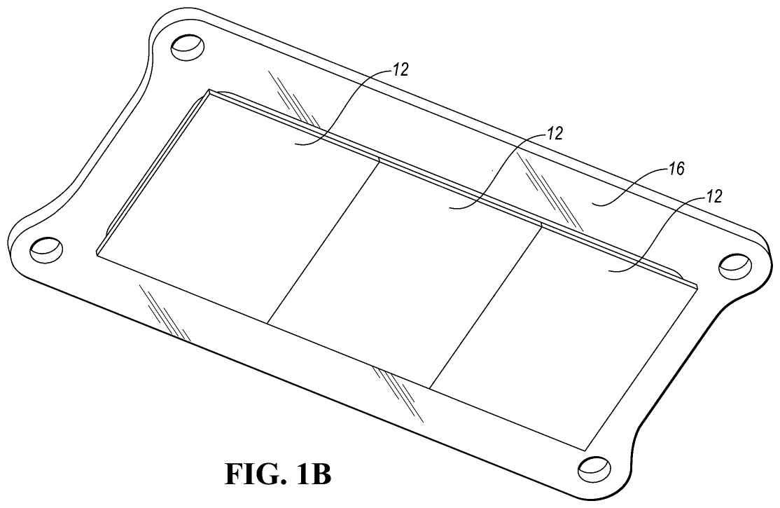

As shown in FIGS. 1A-1B, according to the prior art, a heat sink 10 is shown for dissipating heat from a device capable of generating heat, such an electrical or computer component, an inverter card, or the like. Here, three separate power cards 12 are shown. It should be understood that “power cards” can generally refer to any circuit board that manages or processes power within a system, and that may handle various power-related tasks such as voltage conversion, regulation, distribution, and protection, and DC-to-AC conversion (i.e., inverter card). The power cards 12 may also not necessarily be designed for DC-to-AC conversion, but instead may handle AC-DC conversion, DC-DC conversion, or simply regulate power for different parts of a system. In general, an inverter card can be considered a type of power card due to its power-handling role, but the power card is a broader term intended to refer to any circuit board that manages or processes power and generates heat as a result.

As shown, the heat sink 10 has a base 11 with an upper surface 14 and an opposing lower surface 16. The power card(s) 12 are in direct contact with the lower surface 16. The heat sink 10 also has plurality of fins 18 (e.g., pins, projections, protrusions, or the like) that extend from the base 11 and are configured to increase the surface area of the heat sink for more effective heat transfer. As shown, the fins 18 can extend from the upper surface 14 of the heat sink 10.

Assume an inlet is generally aligned with the right-hand side of the heat sink (as shown by arrow 20) so that an inlet of fluid (e.g., air, liquid, etc.) engages with the fins on the right-hand side of the heat sink, and the fluid travels from right-to-left across the heat sink and between the fins 18, whereupon the fluid exits an outlet of the heat sink (as shown by arrow 22) near the left-hand side of the heat sink 10. As explained above, the fluid becomes warmer as the fluid travels from right-to-left across the heat sink 10. This means that less effective heat transfer takes place on the left-hand side of the heat sink, which can lead to the correspondingly aligned power cards on the left-hand side being subject to less effective heat transfer. In other words, the power cards 12 on the left (closer to the outlet) of the heat sink might not be cooled as effectively as the power cards on the right (closer to the inlet) of the heat sink.

Of course directional terms such as “upper” and “lower” are relative and refer to the orientation shown in the Figures, and is not meant to be limiting on this disclosure unless the context dictates otherwise. For example, in other embodiments, the heat sink is oriented such that the fins 18 extend from lower surface thereof, and the power cards 12 are in contact with the upper surface of the heat sink.

Moreover, it should be understood that when the present disclosure refers to the base being in contact with a heat-generating device, this can include indirect or direct contact. For example, in the case of an indirect contact, a heat-generating component such as a power card may be on a lower side of a board, while the upper side of the board makes direct contact with the base of the heat sink. In the case of direct contact, the heat-generating component may be in a direct face-to-face relationship with the base of the heat sink. Unless otherwise noted, the term contact should refer to both indirect or direct contact.

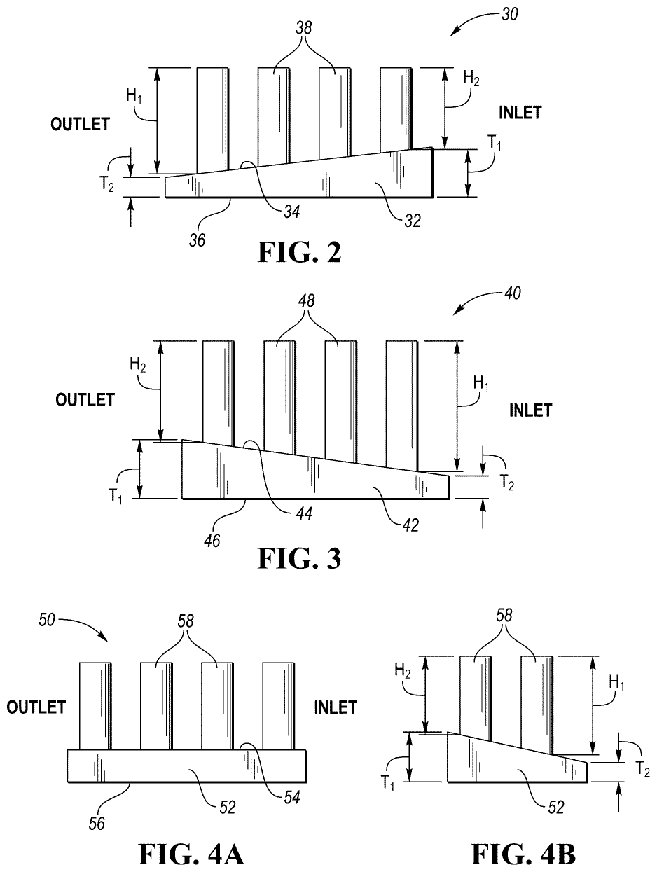

FIG. 2 illustrates a heat sink 30 with a varying base thickness, according to an embodiment. FIG. 2 is a side view of a portion of the heat sink, with the view taken such that the fluid would flow across the heat sink in the right-to-left direction like FIG. 1A. Similar to FIGS. 1A-1B, the heat sink 30 has a base 32 having an upper surface 34 and a lower surface 36, with fins 38 extending from the upper surface 34 of the base 32. Here, the base 32 has a first thickness T₁ at or near the region of the inlet of the heat sink 30 (e.g., the right-hand side of the heat sink 10 of FIG. 1A), and a second thickness T₂ at or near the region of the outlet of the heat sink 30 (e.g., at the left-hand side of the heat sink 10 of FIG. 1A). The thicknesses T₁, T₂ can be defined as the distance between the upper surface 34 and the lower surface 36. Here, as illustrated in FIG. 2, the first thickness T₁ is greater than second thickness T₂.

By positioning a thicker portion of the heat sink base 32 near the coolant inlet and progressively reducing its thickness toward the outlet, the design can optimize heat conduction precisely where it is most effective. Near the inlet, the coolant temperature is at its lowest, maximizing its ability to remove heat from critical heat-generating components efficiently. The increased thickness at this location reduces thermal resistance, facilitating rapid and efficient heat conduction away from the heat source into the coolant.

As the coolant moves toward the outlet, its temperature naturally rises, slightly decreasing its heat-removal efficiency. A thinner base (T₂) at this point appropriately matches this reduced cooling potential, minimizing unnecessary material usage. This also makes way for the pins to be taller, thus improving heat transfer when it is needed more efficiently. For example, as shown in FIG. 2, the pins 38 have a height that varies in the direction from the inlet to the outlet due to the varying base thickness. Fins 38 closer to the outlet have a first height H₁, and fins closer to the inlet have a second height H₂, wherein the first height is greater than the second height H₂. This improves and increases heat transfer at or near the outlet by exposing more of the fluid to additional surface area of the fins. This design ensures a more uniform temperature distribution across the device, improving reliability and longevity of the electronic components.

FIG. 3 illustrates a heat sink 40 with a varying base thickness according to another embodiment. Similar to the embodiment of FIG. 2, the heat sink 40 has a base 42 having an upper surface 44 and a lower surface 46, with fins 48 extending from the upper surface 44 of the base 42. Once again, the base 42 includes a first thickness T₁ that exceeds a second thickness T₂. However, unlike the previous embodiment, here, the first thickness T₁ is located at or near the outlet of the heat sink, while the second thickness T₂ is located at or near the inlet of the heat sink. In other words, the thickness of the heat sink increases in a direction from the inlet to the outlet, which is opposite of the embodiment of FIG. 2.

Consequently, the height of the fins 48 is also the reverse of the previous embodiment. In particular, in FIG. 3, the fins 48 include a first height H₁ at or near the region of the inlet that exceeds a second height H₂ of the fins 38 at or near the region of the outlet. In other words, the fins decrease in height in a direction from the inlet to the outlet.

By progressively increasing the thickness of the heat sink base 42 in the direction of coolant flow, thermal conduction pathways are enhanced in areas where the cooling fluid's temperature has increased, compensating for the reduced cooling effectiveness of the warmer fluid near the outlet. This configuration can result in a more uniform temperature distribution across the heat sink, thereby maintaining effective cooling along the entire heat transfer path. Furthermore, the increased thickness T₁ at the outlet region functions as a thermal mass or buffer, effectively absorbing transient thermal spikes and reducing temperature fluctuations. Such thermal buffering capability contributes significantly to stabilizing the operating temperatures of electronic components under varying or intermittent thermal loads. In addition to thermal advantages, this progressively increasing base thickness also reinforces structural integrity and mechanical stability at critical downstream areas, advantageous in automotive or industrial environments subject to vibration and mechanical stress. This arrangement thus provides an effective means to balance thermal performance, structural robustness, and adaptability to specific operational conditions, while still optimizing overall material usage and associated costs.

In embodiments, the thickness of the base can also vary laterally, i.e., in a direction perpendicular to the direction of the fluid flow. FIGS. 4A-4B illustrate such an example. Here, FIG. 4A is a view taken from a similar standpoint as FIGS. 2-3, showing a side view of a heat sink 50 in a direction such that the fluid flows from the inlet to the outlet in the right-to-left direction. FIG. 4B is a front view (e.g., looking head-on at the outlet-side) of the heat sink 50. Once again, the heat sink 50 has a base 52 having an upper surface 54 and a lower surface 56, with fins 58 extending from the upper surface 54 of the base 52.

As shown in FIG. 4B, the thickness varies in the lateral direction, i.e., in a direction perpendicular to the direction of coolant flow. In particular, the base 52 has a first thickness T₁ that exceeds a second thickness T₂, wherein both T₁ and T₂ can be located the same longitudinal distance from the inlet. Consequently, the fins 58 can also vary in height. For example, some fins in the area of the smaller thickness T₂ can have a first height H₁ that exceeds a second height H₂ of fins in the region of the first thickness T₁.

In this arrangement, the thickness gradient is provided across the width of the heat sink rather than along its length from inlet to outlet. Such a lateral variation provides targeted thermal management advantages, particularly suitable when heat-generating components are unevenly distributed or exhibit localized heat generation across the lateral dimension of the heat sink. For example, the thinner portion of the base (T₂) can be strategically positioned in regions that are vertically aligned (directly above or below) with heat-generating components that yield higher heat flux in the heat sink 50, thus allowing fins with the larger height (H₁) to more effectively cool those regions of the heat sink 50, therefore enhancing localized heat conduction and efficiently transporting thermal energy toward cooler areas where heat can be more effectively dissipated by the fluid. Moreover, this lateral thickness variation allows for an optimized distribution of thermal resistance across the heat sink, effectively smoothing temperature gradients laterally and reducing localized hot spots, thereby extending component life and reliability.

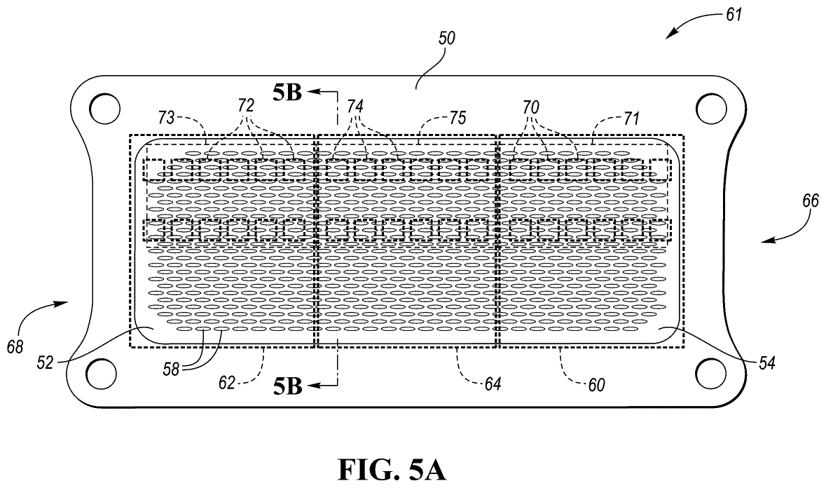

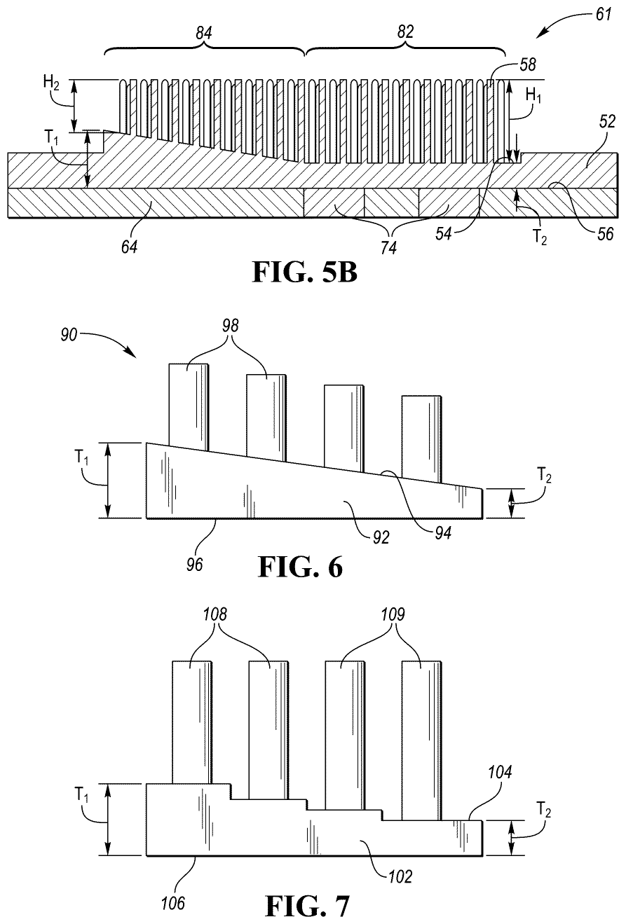

As an example, FIG. 5A-5B illustrates a power inverter assembly 61 according to a first embodiment, wherein FIG. 5A shows a top view of the power inverter assembly 61 and FIG. 5B shows a cross-sectional view of the power inverter assembly 61. The power inverter assembly 61 can include any of the heat sinks described above (30, 40, or 50, etc.), but in the interest of brevity, the power assembly 61 is illustrated as having heat sink 50 from FIGS. 4A-4B. A top surface or upper view of the heat sink 50 is shown in FIG. 5A. Like in previous embodiments, the heat sink 50 has a base 52 having an upper surface 54 and a lower surface 56, with fins 58 extending from the upper surface 54 of the base 52. The lower surface 56 can make direct contact with a plurality of power cards, namely a first power card 60, a second power card 62, and a third power card 64. In the illustrated embodiment, the first power card 60 is located near or adjacent an inlet region 66 of the heat sink 50, and the second power card 62 is located near or adjacent an outlet region 68 of the heat sink 50. In this fashion, fluid that comes in contact with the upper surface 54 of the base 52 near the inlet region 66 will work to cool a region of heat sink 50 aligned with the first power card 60 on the bottom of the heat sink 50, and the fluid that contacts the upper surface 54 of the base 52 near the outlet region 68 will work to cool a region of the heat sink 50 aligned with the second power card 62 on the bottom of the heat sink 50. The third power card 64 is located between the first power card 60 and the second power card 62. Of course, more or less power cards can be provided, and the exact number and arrangement of power cards shown herein is only an example.

Each power card has a group of chips. For example, the first power card 60 has a first group of chips 70, the second power card 62 has a second group of chips 72, and the third power card 64 has a third group of chips 74. The various chips can include microcontrollers or Digital Signal Processors (DSPs), driver ICs, voltage regulators, logic and control ICs, protection ICs, communication ICs, or the like. The chips may be heat-producing objects, and if not properly cooled, excess heat can cause damage and potential system failure, including thermal degradation, electrical overstress, solder joint failures, performance degradation, and the like.

The fins 58 can be spread all across a majority of the upper surface 54 on an opposite side of the heat sink 30 from the chips so as to include a first group or subset of fins 71 generally aligned with the first group of chips 70, a second group of fins 73 generally aligned with the second group of chips 72, and a third group of fins 75 generally aligned with the third group of chips 74.

Assuming fluid travels from the inlet 66 to the outlet 68, the second group of fins 73 (and thereby the second group of chips 72) might be subject to less efficient heat transfer due to the fluid increasing in temperature as it travels from inlet 66 to outlet 68 (e.g., right to left in FIG. 5A). As the fluid travels over the heat sink 50, it first cools the heat sink in the area aligned with the first power card 60, then it cools the heat sink in the area aligned with the third power card 64, and then it finally cools the heat sink in the area aligned with the second power card 62. This can cause inefficient heat transfer, particularly in the area of the heat sink 50 aligned with the second power card 62.

Therefore, as explained above with reference to FIGS. 2-4B, the base 52 may have a varying thickness. For example, as explained with reference to FIGS. 4A-4B, the base 52 may be thinner in regions that are vertically aligned with the heat-generating components (e.g., chips 70, 72, 74), and thicker in regions that are not vertically aligned with the heat-generating components. As shown in FIG. 5B and explained with reference to FIGS. 4A-4B, the base 52 may have a first thickness T₁ on one lateral side thereof, and a second, smaller thickness T₂ on another later side thereof.

This consequently can cause the fins 58 in the area aligned with the heat-generating components (e.g., chips 70, 72, 74) to be longer, and thus improving the heat transfer characteristics of the heat sink 50 in strategic areas. Referring to FIG. 5B, the fins 58 can comprise a first group of fins 82 and a second group of fins 84. The first group of fins 82 can all be of equal height (H₁), while the second group of fins can have a varying height, tapering to a second height H₂ that is less than H₁. This allows fins 82 with the larger height (H₁) to more effectively cool the regions of the heat sink 50 that are vertically aligned with the heat-generating components (e.g., chips 70, 72, 74).

In the embodiment shown in FIG. 5B, roughly half (50%) of the base 52 beneath the fins 58 has a varying thickness. In other words, roughly half of the fins 58 (i.e., the fins in the second group of fins 84) extend from a section of the base 52 that has a varying thickness, while the remaining fins 58 (i.e., the fins in the first group of fins 82) extend from a section of the base 52 with a generally uniform or consistent thickness. However, the present disclosure is not limited to such an arrangement. In other embodiments, 30% or more of the base 52 directly beneath the fins 58 has a varying thickness, while 70% or less of the base 52 directly beneath the fins 58 has a uniform thickness. In other words, the second group of fins 84 can account for 30% or more of the total number of fins in the heat sink 50.

In other embodiments, at least 20% of the base 52 directly beneath the fins 58 has a varying thickness, while 80% or less of the base 52 directly beneath the fins 58 has a uniform thickness. In other words, the second group of fins 84 can account for 20% or more of the total number of fins in the heat sink 50.

In other embodiments, at least 70% of the base 52 directly beneath the fins 58 has a varying thickness, while 30% or less of the base 52 directly beneath the fins 58 has a uniform thickness. In other words, the second group of fins 84 can account for 70% or more of the total number of fins in the heat sink 50.

It should also be understood that when the present disclosure refers to the thickness of the base as tapering or changing in height, this is referring to the area of the base that is directly vertically aligned with the fins. For example, looking at FIG. 5B, the base 52 may have varying thicknesses in areas that are laterally outside of the regions of the fins (e.g., at either far left or right ends of the base). But those thicknesses may vary for material savings or packaging concerns and are not for specific heat transfer implications. This disclosure is intended to focus on the varying thickness of the areas of the base in which the fins extend directly from (i.e., regions of the base that are confined within the outer perimeter of the fins).

It should be understood that the present disclosure is not limited to having fins of uneven height in areas where the base has a varying thickness. For example, FIG. 6 shows an embodiment in which the fins are all of equal height. Here, a heat sink 90 has a base 92 having an upper surface 94 and a lower surface 96, with fins 98 extending from the upper surface 94 of the base 92. Once again, the base 92 includes a first thickness T₁ that exceeds a second thickness T₂. However, unlike the previous embodiments, here, the fins 98 all have the same height, and thus the overall height of the heat sink 90 increases as the base thickness increases. The embodiment of FIG. 6 can be implemented in any of the heat sinks described herein.

It should also be understood that the present disclosure is not limited to having a base thickness that tapers linearly. For example, FIG. 7 shows an embodiment in which the base tapers in a stepped or incremental fashion. Here, a heat sink 100 has a base 102 having an upper surface 104 and a lower surface 106, with fins 108 extending from the upper surface 104 of the base 102. Once again, the base 102 includes a first thickness T₁ that exceeds a second thickness T₂. However, unlike the previous embodiments, here, the thickness of the base 102 is stepped so that each fin 108 extends from a generally planar, flat section of the upper surface 104 that is parallel to the lower surface 106. The base 102 includes multiple discrete levels or steps, each providing a generally planar upper surface substantially parallel to the lower surface 106 of the base, with each fin extending upward from one of these stepped surfaces. This stepped configuration enables precise control over local heat transfer characteristics and structural properties. Specifically, each discrete step can be strategically dimensioned and positioned beneath corresponding heat-generating components to tailor thermal conduction according to the heat flux demands of individual components. The stepped design can further facilitate manufacturing simplicity, as each step provides a flat mounting surface for both fins 108, simplifying formation, assembly and attachment. The embodiment of FIG. 7 can be implemented in any of the heat sinks described herein.

Moreover, in the embodiment illustrated in FIG. 7, the fins 108 can have a varying height that decreases as the thickness of the base increases. This allows an upper surface 109 of the fins to be generally horizontally aligned or coplanar. This arrangement of coplanar upper surfaces is also illustrated in FIGS. 2-4B.

In any of the above embodiments, the heat sink may include a length and a width, wherein the length is longer than the width. For example, in the heat sink illustrated in FIG. 5, the length extends from right to left, which is parallel with the general direction of fluid flow; conversely, the width would extend from top to bottom in this illustrated orientation, perpendicular to the length. A center longitudinal axis can extend along the length and bisect the heat sink into two longitudinal sections. A center lateral axis can extend along the width and bisect the heat sink into two lateral sections. This is shown in FIG. 5B, where the first group of fins 82 are located in one lateral section of the heat sink, and the second group of fins 84 are located in another lateral section of the heat sink.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A heat sink for a power inverter assembly in a motor vehicle, the heat sink comprising:
a base having a lower surface and an opposing upper surface that define a thickness of the base, wherein the lower surface contacts a heat-generating device; and
a plurality of fins extending from the upper surface of the base, wherein the plurality of fins include a first group of fins extending directly from a first region of the base, and a second group of fins extending directly from a second region of the base;
wherein the first region of the base has a first thickness, and the second region of the base has a second thickness that differs from the first thickness.

2. The heat sink of claim 1, wherein at least one of the first thickness and second thickness tapers.

3. The heat sink of claim 2, wherein at least one of the first thickness and the second thickness tapers in a linear fashion.

4. The heat sink of claim 2, wherein at least one of the first thickness and the second thickness tapers in a stepped fashion.

5. The heat sink of claim 1, wherein each of the fins in the first group of fins have a uniform height, and wherein the fins in the second group of fins varying heights.

6. The heat sink of claim 5, wherein the first thickness is less than the second thickness.

7. The heat sink of claim 6, wherein the first thickness is uniform through the first region of the base, and wherein the second thickness tapers within the second region of the base.

8. The heat sink of claim 7, wherein the lower surface of the base at the first region of the base contacts a heat-generating device.

9. The heat sink of claim 8, wherein the lower surface of the base at the second region of the base does not directly contact any heat-generating device.

10. The heat sink of claim 1, wherein the first region of the base is located at or near an inlet of the heat sink, and the second region of the base is located at or near an outlet of the heat sink.

11. The heat sink of claim 1, wherein the first thickness is tapered, the second thickness is tapered, and the first thickness is thicker than the second thickness.

12. The heat sink of claim 11, wherein the fins within both the first group of fins and the second group of fins have upper surfaces that are coplanar with each other.

13. The heat sink of claim 11, wherein the fins within both the first group of fins and the second group of fins have uniform heights.

14. A power inverter assembly for a motor vehicle, the power inverter assembly comprising:
a heat-generating component; and
a heat sink having:
a base that includes a lower surface, an upper surface, and a thickness therebetween, wherein the lower surface contacts the heat-generating component;
an inlet region at or near an inlet of the heat sink;
an outlet region at or near an outlet of the heat sink, wherein fluid flows from the inlet to the outlet; and
a plurality of fins extending from the upper surface of the base, wherein the plurality of fins include a first group of fins in the inlet region and a second group of fins in the outlet region;
wherein the thickness of the base at the inlet region is different than the thickness of the base at the outlet region, and wherein the first group of fins have a different height than the second group of fins.

15. The power inverter assembly of claim 14, wherein the thickness of the base at the inlet region is greater than the thickness of the base at the outlet region, and wherein the first group of fins are shorter than the second group of fins.

16. The power inverter assembly of claim 15, wherein the thickness of the base tapers from the inlet region to the outlet region.

17. The power inverter assembly of claim 15, wherein the thickness of the base tapers in a linear or stepped fashion.

18. A power inverter assembly for a motor vehicle, the power inverter assembly comprising:
a heat sink having a base that includes a lower surface, an upper surface, a thickness therebetween, and a plurality of fins extending from the upper surface of the base, wherein the heat sink includes an inlet region and an outlet region such that fluid flows across the heat sink from the inlet region to the outlet region, and wherein the heat sink has a width extending in a lateral direction and a length extending in a longitudinal direction perpendicular to the lateral direction;
a plurality of heat-generating components contacting the lower surface of the base, wherein the heat-generating components are distributed along a first lateral side of the base, and wherein the base has a second lateral side;
wherein the thickness of the base in the first lateral side is less than the thickness of the base in the second lateral side.

19. The power inverter of claim 18, wherein the thickness of the base within the second lateral side tapers thinner toward the second lateral side.

20. The power inverter of claim 18, wherein the plurality of fins within the first lateral side of the base are longer than the plurality of fins within the second lateral side of the base.
